(19) United States
(12) Patent Application Publication
(10) Pub. No.: US 2014/0335341 A1
(43) Pub. Date: Nov. 13, 2014

(54) CYANATE ESTERS-BASED ADHESIVE RESIN COMPOSITION FOR FABRICATION OF CIRCUIT BOARD AND FLEXIBLE METAL CLAD LAMINATE COMPRISING THE SAME

(71) Applicant: LG CHEM, LTD., Seoul (KR)

(72) Inventors: Young Seok Park, Daejeon (KR); Soon Yong Park, Daejeon (KR); Se Myung Jang, Daejeon (KR)

(73) Assignee: LG CHEM, LTD., Seoul (KR)

(21) Appl. No.: 14/364,978

(22) PCT Filed: Dec. 11, 2012
(86) PCT No.: PCT/KR2012/010743

§ 371 Date: Jun. 12, 2014

(30) Foreign Application Priority Data
Dec. 12, 2011 (KR) 10-2011-0133108
Dec. 11, 2012 (KR) 10-2012-0143418
Dec. 11, 2012 (KR) 10-2012-0143419

(51) Int. Cl. H05K 1/03; H05K 1/05; C09J 147/00

(52) U.S. Cl. CPC H05K 1/0353; C09J 147/00; H05K 1/0366; H05K 1/0393; H05K 1/056; H05K 2201/015; H05K 2201/0145
USPC 428/220; 525/276; 524/520; 428/462

(57) ABSTRACT

The present invention relates to an adhesive resin composition for fabrication of circuit boards and its use. The adhesive resin composition of the present invention includes a cyanate ester resin, a fluorine-based resin powder dispersed in the cyanate ester resin, and a rubber component and has low dielectric constant and low dielectric loss factor, which enables the fabrication of circuit boards with further enhanced electrical characteristics.

### TECHNICAL FIELD

The present invention relates to a cyanate-ester-based adhesive resin composition applicable to the fabrication of printed circuit boards, and uses of the same.

### BACKGROUND OF ART

The recent trends in various electronic components towards thinner and higher density units have lead the use of flexible printed circuit boards in multifarious applications and a gradual increase in the size of the market.

The flexible printed circuit board refers to a substrate endowed with flexibility and bending properties, that is, an electrically insulating substrate on which a conductive pattern to transfer electrical signals is formed. An example of the flexible printed circuit board is a copper clad laminate (CCL), which is a laminate of an electrically insulating film and a copper foil, with an adhesive applied between the electrically insulating film and the copper foil to bond them together. The adhesive may also be used in the manufacture of a coverlay, which is prepared by forming a wiring pattern from the processed copper foil of the copper clad laminate and applying a coating onto the side with the wiring pattern formed on for protection of the wires; a bonding sheet for bonding the copper clad laminate and the coverlay together in the fabrication of a multilayered circuit board; and a prepreg for providing interlaminar insulation and bonding, and hardness for flexible printed circuit boards.

The flexible printed circuit board is basically required to have adhesion between the electrically insulating film and the copper foil, thermal resistance, resistance to solvent, dimensional stability, nonflammability, and so forth. Furthermore, the recent trend of the electronic equipment to higher performance makes a demand on the faster internal signal transfer in the printed circuit boards, hence requiring the lower dielectric constant and the lower dielectric loss factor for materials of all sorts used in the flexible printed circuit boards.

For this reason, there has been suggested a variety of materials or approaches not only to satisfy the basic performances required of the circuit boards but to improve dielectric constant and dielectric loss factor, but with unsatisfactory results in the improvements. Among these, the epoxy-based resin adhesive commonly used in the fabrication of flexible metal clad laminates has a limitation in lowering the dielectric constant and the dielectric loss factor of the laminates due to the dielectric characteristics inherent to the epoxy resins, which limitation is difficult to overcome sufficiently with the use of modified epoxy resins with fluorine functional groups, consequently with a demand on the improvement concerning this problem.

### DETAILED DESCRIPTION OF THE INVENTION

### Technical Problem

It is therefore an object of the present invention to provide an adhesive resin composition having low dielectric constant and low dielectric loss factor and thus being usefully applicable to the fabrication of high-performance circuit boards.

It is another object of the present invention to provide a bonding sheet, a coverlay, a prepreg, and a flexible metal clad laminate that include the adhesive resin composition.

### Technical Solution

Accordingly, the present invention provides an adhesive resin composition for fabrication of a circuit board that includes: a cyanate ester resin; and a fluorine-based resin powder and a rubber component dispersed in the cyanate ester resin.

The adhesive resin composition may include 10 to 90 parts by weight of the fluorine-based resin powder and 1 to 80 parts by weight of the rubber component, with respect to 100 parts by weight of the cyanate ester resin.

The fluorine-based resin powder may have a number average particle diameter of 10 μm or less.

The fluorine-based resin powder may include a powder of at least one fluorine-based resin selected from the group consisting of polytetrafluoroethylene (PTFE), perfluoroalkoxy (PFA) polymer, fluorinated ethylene-propylene (FEP) copolymer, chlorotrifluoroethylene (CTFE), tetrafluoroethylene/chlorotrifluoroethylene (TFE/CTFE) copolymer, ethylene-chlorotrifluoroethylene (ECTFE) copolymer, ethylene-tetrafluoroethylene (ETFE) copolymer, and polychlorotrifluoroethylene (PCTFE).

The cyanate ester resin may include an at least bifunctional aliphatic cyanate ester, an at least bifunctional aromatic cyanate ester, or a mixture thereof.

The rubber component may include at least one rubber selected from the group consisting of natural rubber, styrene butadiene rubber (SBR), isoprene rubber (IR), acrylonitrile butadiene rubber (NBR), ethylene propylene diene monomer (EPDM) rubber, polybutadiene rubber, and modified polybutadiene rubber.

On the other hand, the adhesive resin composition may further include an organic solvent.

The organic solvent may include at least one selected from the group consisting of N,N-dimethylformamide, N,N-dimethylacetamide, acetone, methylethylketone, cyclohexanone, N-methyl-2-pyrrolidone, methyl cellosolve, toluene, methanol, ethanol, propanol, and dioxolane. The adhesive resin composition may include 50 to 500 parts by weight of the organic solvent with respect to 100 parts by weight of the solid composition content.

In accordance with another exemplary embodiment of the present invention, there is provided a bonding sheet that includes a cured material of the adhesive resin composition.

In accordance with further another exemplary embodiment of the present invention, there is provided a coverlay that includes: an electrically insulating film; and the bonding sheet adhered on at least one side of the electrically insulating film.

In accordance with further another exemplary embodiment of the present invention, there is provided a prepreg that includes: a reinforced fiber; and the adhesive resin composition impregnated in the reinforced fiber.

In accordance with still another exemplary embodiment of the present invention, there is provided a flexible metal clad laminate that includes: an electrically insulating film, a metal foil laminated on at least one side of the electrically insulating film, and an adhesive resin layer disposed between the electrically insulating film and the metal foil; wherein the adhesive resin layer includes the above-mentioned adhesive resin composition.

### Advantageous Effects

The adhesive resin composition of the present invention has low dielectric constant and low dielectric loss factor and thus enables the fabrication of circuit boards with further enhanced electrical characteristics.

### BRIEF DESCRIPTION OF THE DRAWINGS

FIGS. 1 and 2 are mimetic cross-sectional views showing the constructions of flexible metal clad laminates according to the respective exemplary embodiments of the present invention.

### DESCRIPTION OF REFERENCE NUMERALS AND SIGNS

10: Electrically insulating film

20, 20′: Adhesive resin layer

30, 30′: Metal foil

### DETAILED DESCRIPTION OF THE EMBODIMENTS

Hereinafter, a detailed description will be given as to the adhesive resin compositions and their uses according to the exemplary embodiments of the present invention.

Before the present invention is described in further detail, it is to be understood that, unless otherwise defined, all the technical terms are given to refer to the particular embodiments of the present invention and not intended to limit the present invention.

As used herein, the singular forms “a”, “an” and “the” are intended to include the plural forms as well, unless the context clearly indicates otherwise.

It will be further understood that the terms “comprises”, “comprising”, “includes” and/or “including”, when used herein, specify the presence of stated features, regions, integers, steps, operations, elements, and/or components, but do not preclude the presence or addition of one or more other features, regions, integers, steps, operations, elements, and/or components.

In the course of the repeated studies on the adhesive resin compositions for fabrication of circuit boards, the inventors of the present invention have found out that a composition including a fluorine-based resin powder dispersed in a cyanate ester resin can secure both lower dielectric constant and lower dielectric loss factor than the conventional epoxy or cyanate resin adhesives and that such a composition enables the fabrication of circuit boards with further enhanced electrical characteristics, thereby completing the present invention.

Conventionally, epoxy resins have been chiefly used as adhesives for fabrication of circuit boards, such as flexible printed circuit boards. For the sake of improving the dielectric characteristics of the epoxy resin adhesives, there have been a variety of methods using fluorine-modified epoxy resins prepared by introducing fluorine functional groups into the epoxy resins. However, the epoxy resins which can be modified with fluorine are limited in their type, which is thus limiting the selection of epoxy resins suitable for the type of a circuit board to fabricate. Moreover, the use of fluorine-modified epoxy resins leads to a rise of the production cost and also has a limitation to secure satisfactorily low dielectric characteristics. Most of all, the inherent properties of the epoxy resins, such as dielectric constant of 3.5 or greater and dielectric loss factor of 0.02 or greater, impose limitations on the use of the epoxy resins in the fields that require low dielectric characteristics.

Unlike the aforementioned epoxy resins or fluorine-modified epoxy resins, the adhesive resin composition of the present invention which is a composition including a fluorine-based resin powder uniformly dispersed in a matrix including a cyanate ester resin does not specifically limit the type of the cyanate ester resin applicable. In addition, the adhesive resin composition of the present invention can include the fluorine-based resin powder in such an amount enough to cause no problem concerning a deterioration of the properties when used in the fabrication of flexible printed circuit boards and thus to minimize the problems associated with a deterioration in the electrical, physical or thermal characteristics of the flexible printed circuit boards which are potentially caused by the inherent properties of the adhesive resin composition.

In accordance with one exemplary embodiment of the present invention, there is provided an adhesive resin composition for fabrication of a circuit board that includes a cyanate ester resin; a fluorine-based resin powder and a rubber component dispersed in the cyanate ester resin.

The cyanate ester resin, which is a base resin, may not be specifically limited as long as it is suitable as an adhesive resin used in the related art. According to the present invention, the cyanate ester resin may be an at least bifunctional aliphatic cyanate ester, an at least bifunctional aromatic cyanate ester, or a mixture of these.

The examples of the cyanate ester resin may include polymers of at least one multifunctional cyanate ester selected from the group consisting of 1,3,5-tricyanatobenzene, 1,3-dicyanatonaphthalene, 1,4-dicyanatenaphthalene, 1,6-dicyanatonaphthalene, 1,8-dicyanatonaphthalene, 2,6-dicyanatonaphthalene, and 2,7-dicyanatonaphthalenate; bisphenol A cyanate ester resins or their hydrogenated derivatives; bisphenol F cyanate ester resins or their hydrogenated derivatives; 6F bisphenol A dicyanate ester resins; bisphenol E dicyanate ester resins; tetramethylbisphenol F dicyanate resins; bisphenol M dicyanate ester resins; dicyclopentadiene bisphenol dicyanate ester resins; or cyanate novolac resins.

The examples of the cyanate ester resins commercially available may include AroCy B (manufactured by Ciba-Geigy, about two cyanate ester groups per molecule on average), AroCy F (manufactured by Ciba-Geigy, about two cyanate ester groups per molecule on average), AroCy L (manufactured by Ciba-Geigy, about two cyanate ester groups per molecule on average), AroCy M (manufactured by Ciba-Geigy, about two cyanate ester groups per molecule on average), RTX 366 (manufactured by Ciba-Geigy, about two cyanate ester groups per molecule on average), XU-71787 (manufactured by Dow Chemical Co., about two cyanate ester groups per molecule on average), Primaset PT-30 (manufactured by Lonza, about two or more cyanate ester groups per molecule on average), BTP-6020 (manufactured by Lonza, about two or more cyanate ester groups per molecule on average), BA-230 (manufactured by Lonza, about two or more cyanate ester groups per molecule on average), BA-3000 (manufactured by Lonza, about two or more cyanate ester groups per molecule on average), and so forth.

On the other hand, the adhesive resin composition of the present invention includes a fluorine-based resin powder dispersed in the cyanate ester resin.

Particularly, the fluorine-based resin powder may have the greater effect to reduce the dielectric constant with a decrease in its particle size. Considering that the thickness of the flexible copper clad laminate is generally about several scores of micrometers, the number average particle diameter of the fluorine-based resin powder may be 10 μm or less, preferably from 0.1 μm to 10 μm, more preferably from 0.1 μm to 7 μm, further more preferably from 0.1 μm to 5 μm.

According to the present invention, the fluorine-based resin powder may be those that have an effect of improving the dielectric characteristics for the composition, preferably a powder of at least one fluorine-based resin selected from the group consisting of polytetrafluoroethylene (PTFE), perfluoroalkoxy (PFA) polymer, fluorinated ethylene-propylene (FEP) copolymer, chlorotrifluoroethylene (CTFE), tetrafluoroethylene/chlorotrifluoroethylene (TFE/CTFE) copolymer, ethylenechlorotrifluoroethylene (ECTFE) copolymer, ethylene-tetrafluoroethylene (ETFE) copolymer, and polychlorotrifluoroethylene (PCTFE).

Among the above-listed fluorine-based resins, a powder of the polytetrafluoroethylene (PTFE) resin having eminently low values of dielectric constant and dielectric loss factor and high glass transition temperature Tg is particularly preferred, in view of securing dielectric characteristics and minimizing a deterioration of the properties of the composition potentially caused by the addition of the fluorine-based resin powder.

Some of the fluorine-based resins, including polyvinyl fluoride (PVF) or polyvinylidene fluoride (PVDF), are not preferred, because they cannot realize such low dielectric characteristics as required in the present invention.

The content of the fluorine-based resin powder in the adhesive resin composition of the present invention may be 10 to 90 parts by weight, preferably 10 to 70 parts by weight, more preferably 20 to 60 parts by weight, with respect to 100 parts by weight of the cyanate ester resin. In other words, the fluorine-based resin powder is preferably included in an amount of 10 parts by weight or greater with respect to 100 parts by weight of the cyanate ester resin, in order to sufficiently realize the desired characteristics pertaining to an addition of the fluorine-based resin powder, such as low dielectric constant, low dielectric loss factor, and low water absorption rate. Further, when the adhesive resin composition contains an excessive amount of the fluorine-based resin powder, the coating layer formed by using the adhesive resin composition can be susceptible to tearing or breaking due to its relatively low mechanical properties. To avoid this problem, the fluorine-based resin powder is preferably included in an amount of 90 parts by weight or less with respect to 100 parts by weight of the cyanate ester resin.

On the other hand, the adhesive resin composition of the present invention may further include a rubber component dispersed in the cyanate ester resin. In other words, the rubber component may be further included in the adhesive resin composition for the sake of providing a backup for ductility, as the composition is required to have sufficiently high ductility in order to be used in the fabrication of flexible printed circuit boards or the like.

The rubber component may be a natural rubber or a synthetic rubber, preferably a synthetic rubber, such as styrene butadiene rubber (SBR), isoprene rubber (IR), acrylonitrile butadiene rubber (NBR), ethylene propylene diene monomer (EPDM) rubber, polybutadiene rubber, modified polybutadiene rubber, etc.

The molecular weight of the synthetic rubber is preferably in the range from 20,000 to 200,000. In other words, the synthetic rubber preferably has a molecular weight of 20,000 or greater in view of securing the minimum thermal stability required of the rubber component. The rubber component with an excessively high molecular weight is deteriorated in solubility to the solvent to increase the viscosity of the composition, which results in poor workability and deteriorated adhesive strength. To avoid this problem, the molecular weight of the synthetic rubber is preferably 200,000 or less.

Among the synthetic rubbers, the EPDM rubber having the ethylene content of about 10 to 40 wt % (with dielectric constant of about 2.4 and dielectric loss factor of about 0.001) is particularly more effective than the SBR (with dielectric constant of about 2.4 and dielectric loss factor of about 0.003) or the NBR (with dielectric constant of about 2.5 and dielectric loss factor of about 0.005) in lowering the dielectric constant and the dielectric loss factor of the resin composition. Further, the EPDM rubber exhibits low water absorption rate, good weather resistance, and excellent electrical insulating properties and thus may be preferably included in the composition of the present invention.

The EPDM rubber is, however, relatively poor in solubility to the solvents, consequently with difficulty in securing miscibility with the cyanate ester resin. Using the SBR can also be taken into account, since the SBR has relatively high solubility to the solvents and dielectric constant and dielectric loss factor equivalent to those of the EPDM rubber.

The content of the rubber component may be from 1 to 80 parts by weight, preferably from 10 to 70 parts by weight, more preferably 20 to 60 parts by weight, with respect to 100 parts by weight of the cyanate ester resin. To realize the minimum effect pertaining to the addition of the rubber component, the content of the rubber composition is preferably 1 part by weight or more with respect to 100 parts by weight of the cyanate ester resin. Using an excessive amount of the rubber component in the composition potentially leads to excessively high fluidity or an abrupt reduction of the adhesive strength and thermal resistance of the composition. To avoid this problem, the content of the rubber composition is preferably 80 parts by weight or less with respect to 100 parts by weight of the cyanate ester resin.

On the other hand, the adhesive resin composition of the present invention may be prepared by a typical method of mixing the cyanate ester resin, the fluorine-based resin powder, and the rubber component together; preferably by dispersing the fluorine-based resin powder in an organic solvent and then mixing the dispersed fluorine-based resin powder with the rubber component and the cyanate ester resin.

Accordingly, the adhesive resin composition of the present invention may further include an organic solvent. In this regard, the type of the organic solvent can be selected in consideration of the type of the fluorine-based resin powder as long as the organic solvent does not have an adverse effect on the properties of the composition. Preferably, the organic solvent may include at least one selected from the group consisting of N,N-dimethylformamide, N,N-dimethylacetamide, acetone, methylethylketone, cyclohexanone, N-methyl-2-pyrrolidone, methyl cellosolve, toluene, methanol, ethanol, propanol, and dioxolane.

The content of the organic solvent may be from 50 to 500 parts by weight, preferably from 100 to 400 parts by weight, more preferably from 100 to 300 parts by weight, with respect to 100 parts by weight of the solid content of the adhesive resin composition. In other words, the content of the organic solvent is preferably controlled within the above-defined range, in view of securing the minimum fluidity and coatability required of the adhesive resin composition and in consideration of the dispersibility of the fluorine-based resin powder and the efficiency of the process of forming an adhesive layer.

In addition, the adhesive resin composition of the present invention may further include a cyanate ester curing accelerator as needed.

The cyanate ester curing accelerator may be organometallic salts or organometallic complexes, such as including, for example, iron, copper, zinc, cobalt, nickel, manganese, tin, etc. More specifically, the examples of the cyanate ester curing accelerator may include organometallic salts, such as manganese naphthenate, iron naphthenate, copper naphthenate, zinc naphthenate, cobalt naphthenate, iron octylate, copper octylate, zinc octylate, cobalt octylate, etc.; or organometallic complexes, such as lead acetylacetonate, cobalt acetylacetonate, etc.

Based on the metal concentration, the content of the cyanate ester curing accelerator may be from 0.05 to 5 parts by weight, preferably 0.1 to 3 parts by weight, with respect to 100 parts by weight of the cyanate ester resin. In other words, the content of the cyanate ester curing accelerator less than 0.05 part by weight with respect to 100 parts by weight of the cyanate ester resin provides insufficient reactivity and curability, while the content of the cyanate ester curing accelerator greater than 5 parts by weight makes it difficult to control the reaction, accelerating the curing reaction or deteriorating formability.

In addition, the composition for forming the adhesive resin layer may further include inorganic particles such as a phosphor-based flame retardant in order to provide nonflammability. The content of the phosphor-based flame retardant may be from 5 to 30 parts by weight, preferably from 10 to 20 parts by weight, with respect to 100 parts by weight of the cyanate ester resin. In other words, the content of the phosphor-based flame retardant is preferably 5 parts by weight or greater with respect to 100 parts by weight of the cyanate ester resin, in view of sufficiently providing the desired effects pertaining to the addition of the phosphor-based flame retardant. An excessive content of the phosphor-based flame retardant may reduce the fluidity and adhesive strength of the composition. To avoid this problem, the content of the phosphor-based flame retardant is preferably 30 parts by weight or less with respect to 100 parts by weight of the cyanate ester resin.

On the other hand, the above-described adhesive resin composition may be used in the fabrication of bonding sheets, coverlays, or prepregs. Such bonding sheets, coverlays, or prepregs are applicable to circuit boards, such as, for example, flexible printed circuit boards (FPCBs) like flexible metal clad laminates, and their use for the fabrication of the circuit boards may secure further enhanced electrical characteristics than the use of the above-described adhesive resin composition.

In accordance with another exemplary embodiment of the present invention, for example, there is provided a bonding sheet including a cured material of the above-described adhesive resin composition.

The bonding sheet may include an adhesive layer including the above-described composition, and a protective layer (e.g., a release film, etc.) for cladding the adhesive layer. In this regard, the protective layer is not specifically limited as long as it peels the adhesive layer off without leaving a damage on the shape of the adhesive layer. According to the present invention, the protective layer may include plastic films, such as polyethylene (PE) film, polypropylene (PP) film, polymethylpentene (TPX®) film, polyester film, etc.; release papers prepared by coating the one side or both sides of a paper material with a polyolefin film, such as the PE or PP film, a TPX film, etc.

The bonding sheet may be fabricated by applying the above-described composition onto the protective layer by using a comma coater or a reverse roll coater to form an adhesive layer, drying the adhesive layer into the semi-cured state, and then laminating a separate protective layer on the adhesive layer.

The thickness of the bonding sheet including the cured material of the above-described adhesive resin composition is determined in consideration of the adhesive strength required of the bonding sheet and the thickness of a circuit board to fabricate and thus not specifically limited. According to the present invention, the thickness of the bonding sheet is preferably from 5 μm to 100 μm.

In accordance with still another exemplary embodiment of the present invention, there is provided a coverlay including an electrically insulating film, and the bonding sheet adhered on at least one side of the electrically insulating film.

The coverlay is a laminate of the bonding sheet including a cured material of the above-described resin composition on at least one side of the electrically insulating film, where a protective layer (i.e., a release film, etc.) may be further adhered on the bonding sheet as needed.

In this regard, the type of the electrically insulating film is not specifically limited as long as it is typically applicable to the flexible copper clad laminates, and may preferably include electrically insulating films treated with cold plasma.

According to the present invention, the electrically insulating film may include polyimide film, liquid crystal polymer film, polyethylene terephthalate film, polyester film, polyparabanate film, polyester ether ketone film, polyphenylene sulfide film, and aramide film; or a film or sheet fabricated by impregnating a substrate including a glass fiber, an aramide fiber, or a polyester fiber with a cyanate ester resin, a polyester resin, or a diarylphthalate resin to be a matrix.

Particularly, the electrically insulating film for coverlay is preferably a polyimide film, more preferably a polyimide film treated with cold plasma, in view of the thermal resistance, dimensional stability, mechanical characteristics, or the like of the coverlay.

The thickness of the electrically insulating film is determined in an adequate range in consideration of electrical insulating properties to the sufficient extent and the thickness and ductility of the object to which the electrically insulating film is applied, and may be preferably in the range from 5 μm to 200 μm, more preferably from 7 μm to 100 μm.

Such a coverlay can be fabricated by applying the above-described composition to the electrically insulating film by using a comma coater or a reverse roll coater to form an adhesive layer, drying the adhesive layer into the semi-cured state (i.e., the dried state of the composition or the state in the course of the curing reaction occurring in part of the composition), and then laminating the above-described protective layer on the adhesive layer.

In accordance with still further another exemplary embodiment of the present invention, there is provided a prepreg including a reinforced fiber, and the above-described adhesive resin composition applied into the reinforced fiber by impregnation.

Here, the prepreg is a no-flow prepreg (i.e., a dust free prepreg) applicable for layer-to-layer insulation and adhesion and may be provided as a sheet fabricated by applying the above-described adhesive resin composition into the reinforced fiber by impregnation and then drying the impregnated reinforced fiber in the semi-cured state.

The reinforced fiber is not specifically limited as long as it is a typical reinforced fiber used in the related art of the present invention, preferably including at least one fiber selected from the group consisting of E glass fiber, D glass fiber, NE glass fiber, H glass fiber, T glass fiber, and aramide fiber. Particularly, the NE glass fiber (with dielectric constant of about 4.8 and dielectric loss factor of about 0.0015) having lower dielectric constant and lower dielectric loss factor than those of the other glass fibers may be preferably used in view of reducing the dielectric constant and the dielectric loss factor of the prepreg to the minimum.

In accordance with still further another exemplary embodiment of the present invention, there is provided a flexible copper clad laminate including the above-described adhesive resin composition.

More specifically, the flexible metal clad laminate includes an electrically insulating film, a metal foil laminated on at least one side of the electrically insulating film, and an adhesive resin layer disposed between the electrically insulating film and the metal foil, wherein the adhesive resin layer may include a cured material of the above-described adhesive resin composition.

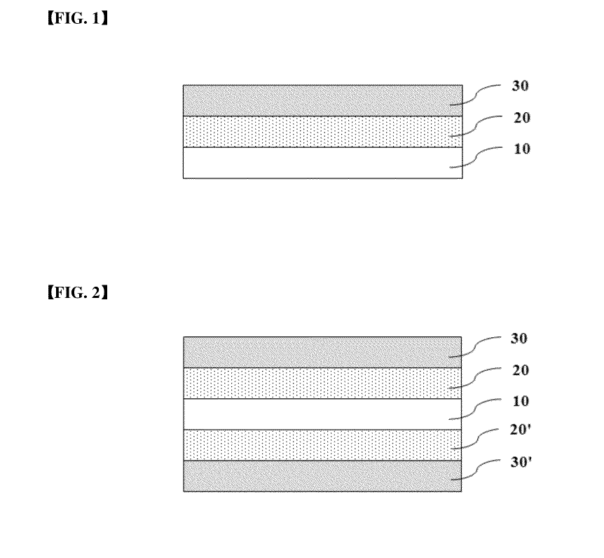

FIGS. 1 and 2 are schematic cross-sectional views of the flexible metal clad laminates according to the preferred embodiments of the present invention, respectively.

Referring to FIG. 1, the flexible metal clad laminate according to one exemplary embodiment of the present invention includes an electrically insulating film 10, a metal foil 30 laminated on the electrically insulating film 10, and an adhesive resin layer 20 disposed between the electrically insulating film 10 and the metal foil 30. In this exemplary embodiment, the electrically insulating film 10 and the metal foil 30 are bonded together by way of the adhesive resin layer 20.

FIG. 1 shows the cross-section of an exemplary embodiment of the flexible metal clad laminate. A flexible metal clad laminate according to another exemplary embodiment of the present invention may have a double-sided structure as shown in FIG. 2. Referring to FIG. 2, metal foils 30 and 30′ are respectively laminated on both sides of an electrically insulating film 10, and adhesive resin layers 20 and 20′ are disposed between the electrically insulating film 10 and the metal foils 30 and 30′, which are thus bonded together.

In the flexible metal clad laminate of the present invention, the electrically insulating film 10 may include, but is not specifically limited to, any typical film used in the related art of the present invention. Preferably, the electrically insulating film may be those that have good thermal resistance, bending properties, and mechanical strengths, and thermal expansion coefficient equivalent to that of metals. Further, the surface of the electrically insulating film may be preferably treated with cold plasma, in view of securing interfacial adhesion with the adhesive resin layer.

According to the present invention, the electrically insulating film may include polyimide film, liquid crystal polymer film, polyethylene terephthalate film, polyester film, polyparabanate film, polyester ether ketone film, polyphenylene sulfide film, and aramide film; or a film or sheet fabricated by impregnating a substrate including a glass fiber, an aramide fiber, or a polyester fiber with a cyanate ester resin, a polyester resin, or a diarylphthalate resin to be a matrix. Particularly, the electrically insulating film may be preferably a polyimide film, in view of securing the thermal resistance, dimensional stability, mechanical characteristics, or the like of the flexible metal clad laminate.

The thickness of the electrically insulating film is determined in an adequate range in consideration of electrical insulating properties to the sufficient extent and the thickness and ductility the flexible metal clad laminate, preferably from 5 μm to 50 μm, more preferably from 7 μm to 45 μm.

In the flexible metal clad laminate of the present invention, the metal foil 30 may be copper (Cu) or copper alloys.

In the case that the metal foil 30 is copper (i.e., a copper foil), the copper foil may be any one typically used in the related art of the present invention. According to the present invention, the copper foil may have a matte side with a roughness (Rz) from 0.1 μm to 2.5 μm, preferably from 0.2 μm to 2.0 μm, more preferably from 0.2 μm to 1.0 μm.

Further, the thickness of the metal foil is determined in consideration of electrical insulating properties, interfacial adhesion with the electrically insulating film, and the ductility of the laminate, preferably 5 μm or greater, more preferably from 7 μm to 35 μm.

On the other hand, the flexible metal clad laminate may be fabricated by applying a composition for forming an adhesive resin layer onto the electrically insulating film 10 to form the adhesive resin layer 20, drying the adhesive layer into the semi-cured state, and then laminating the metal foil 30 on the adhesive resin layer 20, followed by heat compression (i.e., thermal lamination). In this regard, the flexible metal clad laminate is subjected to a post-curing process to completely cure the semi-cured adhesive resin layer 20, thereby completing the final flexible metal clad laminate.

Hereinafter, preferred embodiments are disclosed herein to facilitate an understanding of the present invention, where the following examples are intended to exemplify the present invention and should not be construed as limiting the scope of the present invention.

### EXAMPLE 1

(Preparation of Adhesive Resin Composition)

Polytetrafluoroethylene (PTFE) powder (LUBRON manufactured by DAIKIN, number average particle diameter: about 0.5 μm) and a polyester-based dispersing agent are added to toluene and then dispersed uniformly with a homogenizer (15,000 rpm).

A cyanate ester resin is added to the mixture at the content ratio (based on 100 parts by weight of the cyanate ester resin) given in Table 1 and then completely dissolved with an agitator. To the mixture is added a solution containing 20 wt % of styrene butadiene rubber dissolved in toluene under agitation. Subsequently, cobalt naphthalate as a cyanate ester curing accelerator is added and sufficiently blended into the mixture to prepare a cyanate ester resin composition in which the fluorine resin powder is dispersed.

### EXAMPLES 2 AND 3 AND COMPARATIVE EXAMPLE 1

(Preparation of Adhesive Resin Composition)

The procedures are performed in the same manner as described in Example 1, excepting that the type and content of the cyanate ester resin and the content of the polytetrafluoroethylene powder are varied as given in Table 1, to prepare a cyanate ester resin composition in which the fluorine resin powder is dispersed.

### COMPARATIVE EXAMPLE 2

(Preparation of Adhesive Resin Composition)

Polytetrafluoroethylene (PTFE) powder (LUBRON manufactured by DAIKIN, number average particle diameter: about 0.5 μm) and a polyester-based dispersing agent are added to toluene and then dispersed uniformly with a homogenizer (15,000 rpm).

A bisphenol A epoxy resin and an epoxy-modified polybutadiene rubber are added to the mixture, and pyromellitic dianhydride (PMDA) is then added as an epoxy curing agent and sufficiently blended into the mixture to prepare a bisphenol A epoxy resin composition in which the fluorine-based resin is dispersed.

TABLE 1

| | | | | | Comparative | |
|---|---|---|---|---|---|---|
| | | Example | | | Example | |
| (Content: Part by weight) | | 1 | 2 | 3 | 1 | 2 |
| Cyanate | XU-71787 | 50 | 50 | 50 | 50 | — |
| ester resin | (Dow Chemical) | | | | | |
| | Acrocy B | 50 | — | 20 | 20 | — |
| | (Ciba-Geigy) | | | | | |
| | Primaset PT-30 | — | 50 | 30 | 30 | — |
| | (Lonza) | | | | | |
| Epoxy resin | DER 330 | — | — | — | — | 100 |
| | (Dow Chemical) | | | | | |
| Fluorine- | PTFE Powder | 30 | 30 | 50 | — | 40 |
| based resin | | | | | | |
| powder | | | | | | |
| Rubber | 20% SBR solution | 100 | 100 | 100 | 100 | — |
| component | Epoxy-modified PB | | | | | 20 |
| Curing | Cobalt naphthate | 2 | 2 | — | — | — |
| accelerator | Pyromellitic | — | — | — | — | 10 |
| | dianhydride (PMDA) | | | | | |

PREPARATION EXAMPLES 1 TO 5

(Fabrication of Bonding Sheet)

Each composition according to Examples 1, 2 and 3, or Comparative Examples 1 and 2 is applied onto an about 38 μm thick polyethylene terephthalate film by coating to a dried-film thickness of about 25 μm and dried out at about 150° C. for about 10 minutes. Then, a 100 μm thick release paper (EX3 manufactured by Lintec) with a release coating is laminated on the dry film to fabricate a double-sided thermosetting bonding sheet.

### PREPARATION EXAMPLES 6 TO 10

(Fabrication of Coverlay)

Each composition according to Examples 1, 2 and 3, or Comparative Examples 1 and 2 is applied onto the one side of a polyimide film (manufactured by KANEKA, 12.5 μm thick) by coating to a dry-film thickness of about 25 μm and dried out at about 150° C. for about 10 minutes. Then, a 100 μm thick release paper (EX3 manufactured by Lintec) with a release coating is laminated on the dry film to fabricate a thermosetting coverlay.

PREPARATION EXAMPLES 11 TO 15

### Fabrication of Prepreg

An about 25 μm thick NE glass fiber is impregnated with each composition according to Examples 1, 2 and 3, or Comparative Examples 1 and 2 and then dried out at about 150° C. for about 10 minutes to fabricate a thermosetting prepreg with the total thickness of about 50 μm.

### PREPARATION EXAMPLES 16 TO 20

(Fabrication of Double-Sided Flexible Copper Clad Laminate)

Each composition according to Examples 1, 2 and 3, or Comparative Examples 1 and 2 is applied onto the one side of a polyimide film (manufactured by KANEKA, 12.5 μm thick) by coating to a dry-film thickness of about 10 μm to form an adhesive resin layer, which is then dried into the semi-cured state. The above-stated adhesive resin layer is also formed on the other side of the polyimide film in the same manner to prepare an adhesive sheet.

Subsequently, a copper foil (manufactured by FUKUDA; thickness: about 12 m, roughness (Rz) on the Matte side: 1.6 μm) is laminated on both sides of the adhesive sheet. The resultant laminate is compressed at about 180° C. under the pressure of 30 2 5 kgf/cm² and then cured at about 170° C. for about 5 hours to obtain a double-sided flexible copper clad laminate.

### EXPERIMENT EXAMPLE

Each of the bonding sheets, the coverlays, the prepregs, and the double-sided flexible copper clad laminates according to Preparation Examples 1 to 20 is subjected to the following property evaluations. The specimens used in the evaluations are prepared as in the following methods according to what is tested. The experimental results are presented in Tables 2 to 5.

1. Property Evaluation Method

1-1) Thermal resistance: A specimen cut in the size of 50 mm×50 mm is allowed to absorb water for 12 hours using a pressure cooker tester (120° C., 0.22 MPa) and put in a solder bath at 260° C. for one minute, which specimen is then visually examined. The results are evaluated as ‘X’ (abnormal) or ‘O’ (normal).

1-2) Water absorption rate: The copper foils on both sides of a specimen cut in the size of 50 mm×50 mm are etched, and the specimen is immersed in distilled water for 24 hours. The specimen is weighed to compare the weight before and after the water immersion to calculate the water absorption rate.

1-3) Dielectric characteristics: The dielectric constant and the dielectric loss factor are measured at 1 MHz using an impedance analyzer according to the testing standards of JIS C6481.

1-4) Adhesive strength: A specimen cut in the size of 100 mm×10 mm is measured in regard to the adhesive strength of the adhesive layer formed from each composition using a universal testing machine (UTM).

1-5) Bending properties: The bending properties are measured according to the testing standards of JIS C5016.

2. Preparation of Specimen for Property Evaluation and Evaluation Results

2-1) Bonding sheet: Each bonding sheet according to the Preparation Examples 1 to 5 is adhered in the form of [the polyimide side of the single-sided flexible metal laminate/bonding sheet (25 μm)/polyimide film (12.5 μm)] and then cured by compression under the pressure of 30 kgf/cm² for 60 minutes, with the top and bottom sheets positioned under a hot press machine heated at 180° C., to prepare a specimen.

The evaluation results of the properties are presented in Table 2.

TABLE 2

| | Prepara- | Prepara- | Prepara- | Prepara- | Prepara- |
|---|---|---|---|---|---|
| | tion | tion | tion | tion | tion |
| | Example 1 | Example 2 | Example 3 | Example 4 | Example 5 |
| Adhesive | Example 1 | Example 2 | Example 3 | Com- | Com- |
| composition | | | | parative | parative |
| | | | | Example 1 | Example 2 |
| Dielectric | 2.5 | 2.5 | 2.4 | 2.9 | 2.8 |
| constant | | | | | |
| (ε) | | | | | |
| Dielectric | 0.005 | 0.006 | 0.004 | 0.007 | 0.018 |
| loss factor | | | | | |
| (tanδ) | | | | | |
| Thermal | ◯ | ◯ | ◯ | ◯ | ◯ |
| resistance | | | | | |
| Water | 0.9 | 0.8 | 0.6 | 1.2 | 1.2 |
| absorption | | | | | |
| rate (%) | | | | | |
| Adhesive | 1.5 | 1.6 | 1.2 | 1.8 | 1.2 |
| strength | | | | | |
| (kgf/cm²) | | | | | |

2-2) Coverlay: Each coverlay according to Preparation Examples 6 to 10 is adhered in the form of [the polyimide film of the coverlay/the adhesive side of the coverlay/the shiny side of the copper foil (12 μm)] and then cured by compression under the pressure of 30 kgf/cm² for 60 minutes, with the top and bottom sheets positioned under a hot press machine heated at 180° C., to prepare a specimen.

The evaluation results of the properties are presented in Table 3.

TABLE 3

| | | | | | Prepara- |
|---|---|---|---|---|---|
| | Prepara- | Prepara- | Prepara- | Prepara- | tion |
| | tion | tion | tion | tion | Exam- |
| | Example 6 | Example 7 | Example 8 | Example 9 | ple 10 |
| Adhesive | Example 1 | Example 2 | Example 3 | Com- | Com- |
| composition | | | | parative | parative |
| | | | | Example 1 | Example 2 |
| Dielectric | 2.6 | 2.6 | 2.5 | 3.0 | 2.9 |
| constant (ε) | | | | | |
| Dielectric | 0.004 | 0.005 | 0.003 | 0.006 | 0.016 |
| loss factor | | | | | |
| (tanδ) | | | | | |
| Thermal | ◯ | ◯ | ◯ | ◯ | ◯ |
| resistance | | | | | |
| Adhesive | 1.5 | 1.5 | 1.4 | 1.7 | 1.2 |
| strength | | | | | |
| (kgf/cm²) | | | | | |

2-3) Prepreg: Each prepreg according to Preparation Examples 11 to 15 is adhered in the form of [the polyimide side of the single-sided flexible metal laminate/prepreg (50 μm)/polyimide film (12.5 μm)] and then cured by compression under the pressure of 30 kgf/cm² for 60 minutes, with the top and bottom sheets positioned under a hot press machine heated at 180° C., to prepare a specimen.

The evaluation results of the properties are presented in Table 4.

TABLE 4

| | Prepara- | Prepara- | Prepara- | Prepara- | Prepara- |
|---|---|---|---|---|---|
| | tion | tion | tion | tion | tion |
| | Exam- | Exam- | Exam- | Exam- | Exam- |
| | ple 11 | ple12 | ple 13 | ple 14 | ple 15 |
| Adhesive | Exam- | Exam- | Exam- | Com- | Com- |
| composition | ple 1 | ple 2 | ple 3 | parative | parative |
| | | | | Example 1 | Example 2 |
| Dielectric constant | 3.4 | 3.5 | 3.3 | 4.0 | 3.9 |
| (ε) | | | | | |
| Dielectric loss | 0.004 | 0.005 | 0.004 | 0.006 | 0.015 |
| factor (tanδ) | | | | | |
| Thermal resistance | ◯ | ◯ | ◯ | ◯ | ◯ |
| Adhesive strength | 1.4 | 1.5 | 1.2 | 1.6 | 1.4 |
| (kgf/cm²) | | | | | |

2-4) Double-sided flexible copper clad laminate: Each double-sided flexible copper clad laminate according to the Preparation Examples 16 to 20 is used as a specimen, and the results of the property evaluations are presented in Table 5.

TABLE 5

| | Prepara- | Prepara- | Prepara- | Prepara- | Prepara- |
|---|---|---|---|---|---|
| | tion | tion | tion | tion | tion |
| | Exam- | Exam- | Exam- | Exam- | Exam- |
| | ple 16 | ple 17 | ple 18 | ple 19 | ple 20 |
| Adhesive | Exam- | Exam- | Exam- | Com- | Com- |
| composition | ple 1 | ple 2 | ple 3 | parative | parative |
| | | | | Example 1 | Example 2 |
| Dielectric constant | 2.7 | 2.8 | 2.6 | 3.1 | 3.0 |
| (ε) | | | | | |
| Dielectric loss | 0.004 | 0.005 | 0.003 | 0.006 | 0.015 |
| factor (tanδ) | | | | | |
| Thermal resistance | ◯ | ◯ | ◯ | ◯ | ◯ |
| Water absorption | 1.2 | 0.9 | 0.7 | 0.7 | 1.4 |
| rate (%) | | | | | |
| Bending property | 54 | 74 | 58 | 68 | 43 |
| (time) | | | | | |
| Adhesive strength | 1.2 | 1.3 | 1.1 | 1.2 | 1.2 |
| (kgf/cm²) | | | | | |

As can be seen from Tables 2 to 5, the adhesive resin compositions according to Examples 1, 2 and 3 have low dielectric constant and low dielectric loss factor, and the bonding sheet, the coverlay, the prepreg, and the double-sided flexible copper clad laminate as prepared by using the adhesive resin compositions are equivalent in thermal resistance and adhesive strength but superior in low dielectric characteristics to those prepared by using the adhesive resin composition according to Comparative Example 1. In addition, the bonding sheet, the coverlay, the prepreg, and the double-sided flexible copper clad laminate as prepared by using the adhesive resin compositions according to Examples 1, 2 and 3 exhibit much more remarkably enhanced dielectric characteristics than those prepared by using the adhesive resin composition of Comparative Example 2.

1. An adhesive resin composition for fabrication of a circuit board, comprising:
a cyanate ester resin; and
a fluorine-based resin powder and a rubber component dispersed in the cyanate ester resin.

2. The adhesive resin composition as claimed in claim 1, wherein the adhesive resin composition comprises 10 to 90 parts by weight of the fluorine-based resin powder and 1 to 80 parts by weight of the rubber component, with respect to 100 parts by weight of the cyanate ester resin.

3. The adhesive resin composition as claimed in claim 1, wherein the fluorine-based resin powder has a number average particle diameter of 10 μm or less.

4. The adhesive resin composition as claimed in claim 1, wherein the fluorine-based resin powder comprises a powder of at least one fluorine-based resin selected from the group consisting of polytetrafluoroethylene (PTFE), perfluoroalkoxy (PFA) polymer, fluorinated ethylene-propylene (FEP) copolymer, chlorotrifluoroethylene (CTFE), tetrafluoroethylene/chlorotrifluoroethylene (TFE/CTFE) copolymer, ethylenechlorotrifluoroethylene (ECTFE) copolymer, ethylene-tetrafluoroethylene (ETFE) copolymer, and polychlorotrifluoroethylene (PCTFE).

5. The adhesive resin composition as claimed in claim 1, wherein the cyanate ester resin comprises an at least bifunctional aliphatic cyanate ester, an at least bifunctional aromatic cyanate ester, or a mixture thereof.

6. The adhesive resin composition as claimed in claim 1, wherein the rubber component comprises at least one rubber selected from the group consisting of natural rubber, styrene butadiene rubber (SBR), isoprene rubber (IR), acrylonitrile butadiene rubber (NBR), ethylene propylene diene monomer (EPDM) rubber, polybutadiene rubber, and modified polybutadiene rubber.

7. The adhesive resin composition as claimed in claim 1, further comprising an organic solvent.

8. The adhesive resin composition as claimed in claim 7, wherein the organic solvent comprises at least one selected from the group consisting of N,N-dimethylformamide, N,N-dimethylacetamide, acetone, methylethylketone, cyclohexanone, N-methyl-2-pyrrolidone, methyl cellosolve, toluene, methanol, ethanol, propanol, and dioxolane.

9. The adhesive resin composition as claimed in claim 7, wherein the adhesive resin composition comprises 50 to 500 parts by weight of the organic solvent with respect to 100 parts by weight of the solid composition content.

10. A flexible metal clad laminate comprising:
an electrically insulating film, a metal foil laminated on at least one side of the electrically insulating film, and an adhesive resin layer disposed between the electrically insulating film and the metal foil;
wherein the adhesive resin layer comprising the adhesive resin composition as claimed in claim 1.

11. The flexible metal clad laminate as claimed in claim 10, wherein the electrically insulating film comprises at least one film selected from the group consisting of polyimide film, liquid crystal polymer film, polyethylene terephthalate film, polyester film, polyparabanate film, polyester ether ketone film, polyphenylene sulfide film, and aramide film.

12. The flexible metal clad laminate as claimed in claim 10, wherein the metal foil comprises copper or copper alloys.

13. A bonding sheet comprising a cured material of the adhesive resin composition as claimed in claim 1 and having a thickness of 5 to 100 μm.

14. A coverlay comprising:
an electrically insulating film; and
the bonding sheet as claimed in claim 13 adhered on at least one side of the electrically insulating film.

15. A prepreg comprising:
a reinforced fiber; and
the adhesive resin composition as claimed in claim 1 impregnated in the reinforced fiber.

16. The prepreg as claimed in claim 15, wherein the reinforced fiber comprises at least one fiber selected from the group consisting of E glass fiber, D glass fiber, NE glass fiber, H glass fiber, T glass fiber, and aramide fiber.
